(19) United States
(12) Patent Application Publication
(10) Pub. No.: US 2025/0264501 A1
(43) Pub. Date: Aug. 21, 2025

(54) SELF-COMPENSATED ELECTRICAL SENSOR

(71) Applicant: G & W Electric Company, Bolingbrook, IL (US)

(72) Inventors: Mattewos Tefferi, Naperville, IL (US); Elisa Scala, Bologna (IT); Nenad Uzelac, St. John, IN (US); Abbas Ghaderi, Bologna (IT)

(21) Appl. No.: 18/583,672

(22) Filed: Feb. 21, 2024

(51) Int. Cl. G01R 15/16; G01R 19/00

(52) U.S. Cl. CPC G01R 15/16; G01R 19/0084

(57) ABSTRACT

An electrical sensor may include an electrode. The electrical sensor may include a first capacitive divider electrically coupled between the electrode and ground, the first capacitive divider including a first output. The electrical sensor may include a second capacitive divider electrically coupled between the first output and ground, the second capacitive divider including a second output. The electrical sensor may include a compensating circuit configured to receive, as inputs, the first output and the second output and to output a compensated voltage signal corresponding to a voltage of the electrode.

### BACKGROUND

The present disclosure relates to electrical sensors, and, more specifically, to capacitive voltage sensors.

### SUMMARY

Capacitive voltage sensors are a type of electrical sensor used in power generation, transmission, and/or distribution systems. Capacitive voltage sensors can measure or detect voltage in an electrode without being in direct contact with the electrode and are typically separated from the electrode by a dielectric material. Capacitive voltage sensors may be subject to irreversible degradation of dielectric material over time. Any aging phenomenon diminishes the electrical sensor's accuracy. Capacitive voltage sensors may also be susceptible to inaccuracies if influenced by external electrical fields, such as from nearby electrical systems, cables, etc.

The present disclosure provides, among other things, an electrical sensor including a two-capacitive divider arm for self-compensation. In some embodiments, the electrical sensor includes concentric conductors forming terminals of capacitors in the capacitive divider arms. The concentric conductors are protected from external electrical fields by concentric shields, which may also extend beyond of the concentric conductors. In some embodiments, the electrical sensor can maintain metering class accuracy of 0.2% to meet IEC standards 60044/61869.

For example, in some aspects, the techniques described herein relate to an electrical sensor including: an electrode; a first capacitive divider electrically coupled between the electrode and ground, the first capacitive divider including a first output; a second capacitive divider electrically coupled between the first output and ground, the second capacitive divider including a second output; and a compensating circuit configured to receive, as inputs, the first output and the second output and to output a compensated voltage signal corresponding to a voltage of the electrode.

In some aspects, the techniques described herein relate to an electrical sensor, wherein: the first capacitive divider includes a first capacitor and a second capacitor, the second capacitive divider includes a third capacitor and a fourth capacitor, the first capacitor and the third capacitor include a first type of dielectric material, the second capacitor and the fourth capacitor includes a second type of dielectric material, and the second type of dielectric material is different than the first type of dielectric material.

In some aspects, the techniques described herein relate to an electrical sensor, further including: an inner tubular body surrounding and spaced radially outwardly from the electrode, the inner tubular body including a first inner conductive layer configured to form a first capacitive coupling with the electrode, a first shield surrounding the first inner conductive layer, and a first insulator disposed between the first inner conductive layer and the first shield; an intermediate tubular body surrounding the inner tubular body, the intermediate tubular body including a conductive material; an outer tubular body surrounding and spaced radially outwardly from the intermediate tubular body, the outer tubular body including a second inner conductive layer configured to form a second capacitive coupling with the conductive material of the intermediate tubular body, a second shield surrounding the second inner conductive layer, and a second insulator disposed between the second inner conductive layer and the second shield; and a molded body encapsulating the inner tubular body, the intermediate tubular body, and the outer tubular body, the molded body made of the first type of dielectric material.

In some aspects, the techniques described herein relate to an electrical sensor, wherein the electrode, the first inner conductive layer, and the molded body form the first capacitor, and wherein the conductive material of the intermediate tubular body, the second inner conductive layer, and the molded body form the third capacitor.

In some aspects, the techniques described herein relate to an electrical sensor, wherein the compensated voltage signal output by the compensating circuit has an error with a magnitude of 0.2% or less over an ambient temperature range of −5 degrees C. to 60 degrees C.

In some aspects, the techniques described herein relate to an electrical sensor, wherein the compensated voltage signal output by the compensating circuit has an error with a magnitude of 0.3% or less over an ambient temperature range of −40 degrees C. to 60 degrees C.

In some aspects, the techniques described herein relate to an electrical sensor including: an electrode extending along an axis; an inner tubular body surrounding and spaced radially outwardly from the electrode, the inner tubular body including a first inner conductive layer configured to form a first capacitive coupling with the electrode, a first shield surrounding the first inner conductive layer, and a first insulator disposed between the first inner conductive layer and the first shield; an intermediate tubular body surrounding the inner tubular body, the intermediate tubular body including a conductive material; an outer tubular body surrounding and spaced radially outwardly from the intermediate tubular body, the outer tubular body including a second inner conductive layer configured to form a second capacitive coupling with the conductive material of the intermediate tubular body, a second shield surrounding the second inner conductive layer, and a second insulator disposed between the second inner conductive layer and the second shield; and a dielectric material encapsulating the inner tubular body, the intermediate tubular body, and the outer tubular body.

In some aspects, the techniques described herein relate to an electrical sensor, wherein the electrode, the inner tubular body, the intermediate tubular body, and the outer tubular body are concentric.

In some aspects, the techniques described herein relate to an electrical sensor, wherein the inner tubular body includes a flexible printed circuit board.

In some aspects, the techniques described herein relate to an electrical sensor, wherein the outer tubular body includes a flexible printed circuit board.

In some aspects, the techniques described herein relate to an electrical sensor, wherein the first inner conductive layer is electrically coupled to the conductive material of the intermediate tubular body.

In some aspects, the techniques described herein relate to an electrical sensor, further including a first amplifier electrically coupled between the first inner conductive layer and the intermediate tubular body.

In some aspects, the techniques described herein relate to an electrical sensor, further including a second amplifier electrically coupled to the second inner conductive layer.

In some aspects, the techniques described herein relate to an electrical sensor, wherein the first amplifier is configured to amplify a first voltage signal from the first inner conductive layer to an amplified first voltage signal having a first order of magnitude, wherein the amplified first voltage signal is applied to the conductive material of the intermediate tubular body, wherein the second amplifier is configured to amplify a second voltage signal from the second inner conductive layer to an amplified second voltage signal having a second order of magnitude, and wherein the second order of magnitude is equal to the first order of magnitude.

In some aspects, the techniques described herein relate to an electrical sensor, further including a compensating circuit configured to receive the amplified first voltage signal as a first input and the amplified second voltage signal as a second input.

In some aspects, the techniques described herein relate to an electrical sensor, wherein the compensating circuit is configured to output a compensated voltage signal corresponding to a voltage of the electrode.

In some aspects, the techniques described herein relate to an electrical sensor, further including a third shield extending from a first end of the inner tubular body.

In some aspects, the techniques described herein relate to an electrical sensor, further including a fourth shield extending from a second end of the inner tubular body opposite the first end.

In some aspects, the techniques described herein relate to an electrical sensor, wherein the first shield, and second shield, the third shield, and the fourth shield are grounded.

In some aspects, the techniques described herein relate to an electrical sensor including: an electrode extending along an axis; a first conductor configured to form a first capacitive coupling with the electrode; an intermediate conductor electrically coupled to the first conductor; a second conductor configured to form a second capacitive coupling with the intermediate conductor; and a compensating circuit electrically coupled to the first conductor and the second conductor, wherein the compensating circuit is configured to output a compensated voltage signal corresponding to a voltage of the electrode.

In some aspects, the techniques described herein relate to an electrical sensor, wherein the first conductor, the intermediate conductor, and the second conductor are encapsulated within a dielectric material.

In some aspects, the techniques described herein relate to an electrical sensor, further including a first amplifier electrically coupled between the first conductor and the intermediate conductor; and a second amplifier electrically coupled to the second conductor.

In some aspects, the techniques described herein relate to an electrical sensor, wherein the first amplifier is configured to amplify a first voltage signal from the first conductor to an amplified first voltage signal having a first order of magnitude, wherein the second amplifier is configured to amplify a second voltage signal from the second conductor to an amplified second voltage signal having a second order of magnitude equal to the first order of magnitude, and wherein the compensating circuit is configured to receive the amplified first voltage signal as a first input and the amplified second voltage signal as a second input.

In some aspects, the techniques described herein relate to an electrical sensor, further including a first shield surrounding the first conductor and a second shield surrounding the second conductor, wherein the intermediate conductor is disposed radially between the first shield and the second shield.

Other aspects of the disclosure will become apparent by consideration of the detailed description and accompanying drawings.

### BRIEF DESCRIPTION OF THE DRAWINGS

FIG. 1 is a perspective view of a bushing incorporating an electrical sensor according to an embodiment of the present disclosure.

FIG. 2 is a perspective view of the bushing of FIG. 1 with a dielectric body of the bushing hidden to illustrate the electrical sensor.

FIG. 3A is a cross-sectional view taken along line A-A in FIG. 1, with the dielectric body and an intermediate tubular body of the bushing hidden.

FIG. 3B is an enlarged cross-sectional view of a portion of the electrical sensor of FIG. 2, taken along line A-A in FIG. 1.

FIG. 4 is a cross-sectional view of the bushing of FIG. 1, taken along line A-A in FIG. 1.

FIG. 5 is a cross-sectional view of the bushing of FIG. 1, taken along line B-B in FIG. 1.

FIG. 6 illustrates a circuit diagram of the electrical sensor of FIG. 2.

FIG. 7 is a plot of experimental test results illustrating the accuracy of the electrical sensor of FIG. 2 at varying temperatures within a first range.

FIG. 8 is a plot of experimental test results illustrating the accuracy of the electrical sensor of FIG. 2 at varying temperatures within a second range.

FIG. 9 is a side view of an outdoor overhead voltage sensor assembly incorporating an electrical sensor according to an embodiment of the present disclosure.

FIG. 10 is a cross-sectional view of the sensor assembly of FIG. 9, taken along line 10-10 in FIG. 9.

FIG. 11 is a cross-sectional view illustrating the electrical sensor of the overhead voltage sensor assembly of FIG. 9.

FIG. 12 is a schematic illustration of a switchgear apparatus incorporating an electrical sensor according to an embodiment of the present disclosure.

Before any embodiments of the disclosure are explained in detail, it is to be understood that the disclosure is not limited in its application to the details of construction and the arrangement of components set forth in the following description or illustrated in the accompanying drawings. The disclosure is capable of supporting other embodiments and of being practiced or of being carried out in various ways.

### DETAILED DESCRIPTION

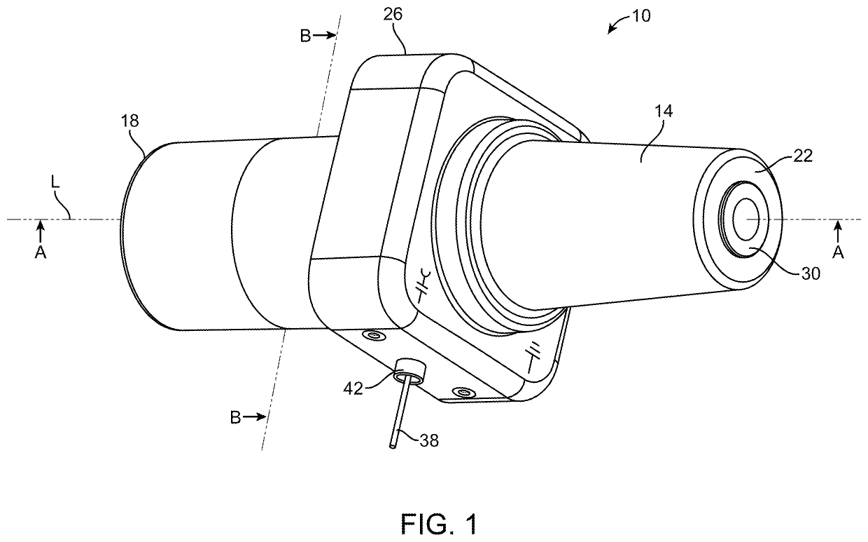

FIG. 1 illustrates a feedthrough device in the form of a bushing 10, which may be used for coupling an accessory (not shown), such as a cable, bus bar, or the like, to a terminal of an electrical device, such as a transformer, switchgear apparatus, disconnect switch, etc.

With continued reference to FIG. 1, the illustrated bushing 10 includes a body 14 having a first end 18, a second end 22 opposite the first end 18, and a flange portion 26 between the first and second ends 18, 22. The first end 18 is configured to be coupled to (and in some embodiments, at least partially received within) a terminal of the electrical device. In some embodiments, the flange portion 26 may abut and/or attach to a body (e.g., tank) of the electrical device. The second end 22 is configured to be coupled to the accessory. In some embodiments, the bushing 10 may include a standardized interface (such as an IEC or IEEE standardized interface) at the first end 18 and/or the second end 22.

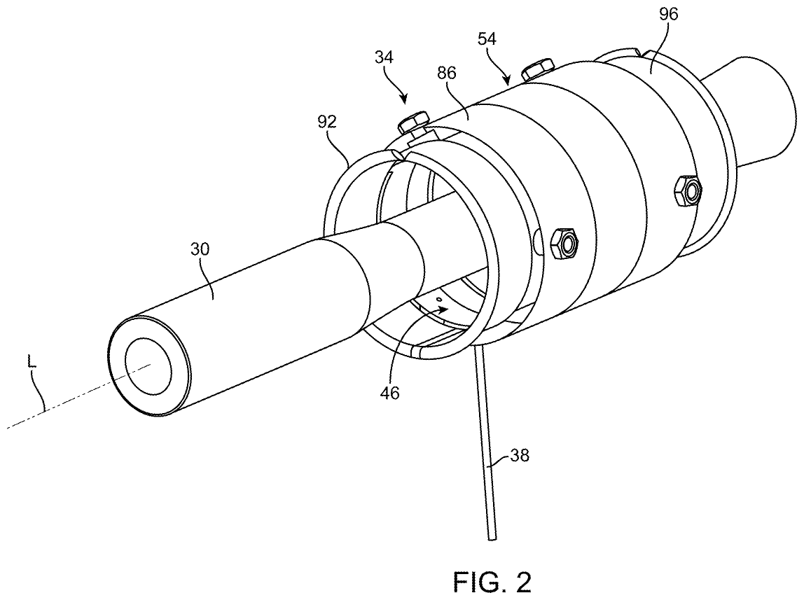

Referring to FIGS. 1-2, an electrode 30 extends along a longitudinal axis L between the first and second ends 18, 22, such that the bushing 10 may electrically connect the accessory and the electrical device through the electrode 30. The body 14 of the illustrated bushing 10 is made of a solid dielectric material, which may be a molded dielectric material, such as an epoxy resin. In some embodiments, the epoxy resin may be a cycloaliphatic epoxy resin. The solid dielectric material has a high dielectric constant suitable for insulating the electrode 30 at the operating voltage range of the electrical device.

The illustrated bushing 10 includes an electrical sensor 34 configured to measure a voltage of the electrode 30 and to communicate a signal corresponding to the measured voltage via an output 38 (FIGS. 1, 2). In the illustrated embodiment, the output 38 includes a wire extending through a port 42 in the flange portion 26 of the body 14 (FIG. 1); however, in other embodiments, the output 38 may be routed elsewhere through the body 14. Alternatively, the output 38 may be a wireless signal.

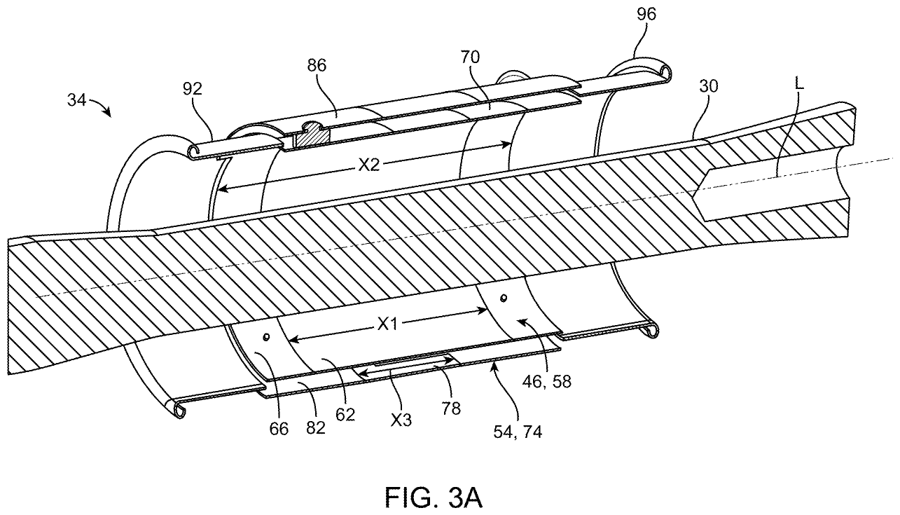

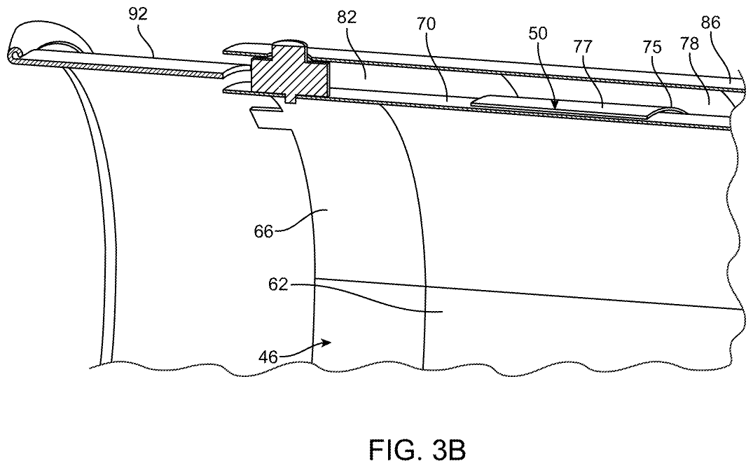

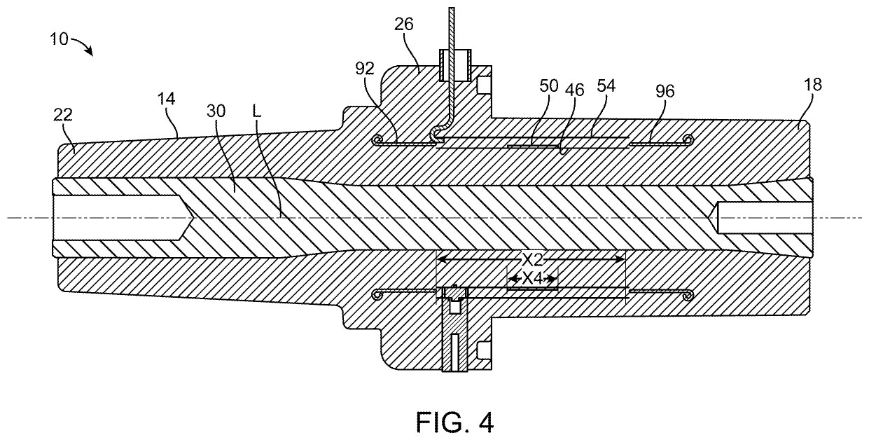

Referring to FIGS. 3A-5, the illustrated sensor 34 includes an inner tubular body 46 surrounding and spaced radially outwardly from the electrode 30, an intermediate tubular body 50 (FIGS. 4-5) surrounding the inner tubular body 46, and an outer tubular body 54 surrounding and spaced radially outwardly from the intermediate tubular body 50. The tubular bodies 46, 50, 54 are encapsulated by the dielectric material of the body 14. In the illustrated embodiment, the inner tubular body 46 includes a flexible printed circuit board 58 having an inner conductive layer 62 (e.g., made of copper), which may also be referred to as a first inner conductive layer 62 or a first conductor 62, an insulator in the form of an insulating layer or substrate 66 (e.g., made of fiberglass, polyimide, or the like), and an outer conductive layer 70 (e.g., made of copper), which may also be referred to as a first shield 70 (FIGS. 3A-3B). The insulating layer 66 is disposed between the inner conductive layer 62 and the outer conductive layer 70 to electrically isolate the inner conductive layer 62 from the outer conductive layer 70.

Similarly, the outer tubular body 54 includes a flexible printed circuit board 74 having an inner conductive layer 78 (e.g., made of copper), which may also be referred to as a second inner conductive layer 78 or a second conductor 78, an insulator in the form of an insulating layer or substrate 82 (e.g., made of fiberglass, polyimide, or the like), and an outer conductive layer 86 (e.g., made of copper), which may also be referred to as a second shield 86. The insulating layer 82 is disposed between the inner conductive layer 78 and the outer conductive layer 86 to electrically isolate the inner conductive layer 78 from the outer conductive layer 86.

The intermediate tubular body 50 includes an insulator in the form of an insulating layer or substrate 75 (e.g., made of fiberglass, polyimide, or the like) surrounding the first shield 70 and an outer conductive layer 77 (e.g., made of copper) facing the inner conductive layer 78 of the outer tubular body 54 (FIG. 3B). In some embodiments, the intermediate tubular body 50 may be attached to and supported by the inner tubular body 46. In such embodiments, the insulating layer 75 of the intermediate tubular body 50 may be adhered to the first shield 70; however, the intermediate tubular body 50 may alternatively be attached to the inner tubular body 46 in other ways. In yet other embodiments, the intermediate tubular body 50 may be radially spaced apart from the inner tubular body 46.

Referring to FIGS. 3A-3B, illustrated sensor 34 further includes a third shield 92 and a fourth shield 96 extending from opposite ends of the inner tubular body 46. The third shield 92 and the fourth shield 96 are each made of a conductive material (such as a copper or brass mesh) in the illustrated embodiment. The shields 70, 86, 92, 96 are grounded and inhibit external electrical fields from interacting with and affecting the accuracy of the sensor 34.

As illustrated in FIG. 3A, the inner conductive layer 62 of the inner tubular body 46 has a first length X1 parallel to the longitudinal axis L of the electrode 30, and the insulating layer 66 of the inner tubular body 46 has a second length X2 parallel to the longitudinal axis L. The first shield 70 is coextensive with the insulating layer 66, such that the first shield 70 extends along the entire outer surface of the insulating layer 66. The inner conductive layer 78 of the outer tubular body 54 has a third length X3 parallel to the longitudinal axis L. The insulating layer 82 of the outer tubular body 54 is the same length X2 as the insulating layer 66; however, the insulating layer 82 may be shorter or longer than the insulating layer 66 in other embodiments. The second shield 86 is coextensive with the insulating layer 82, such that the second shield 86 extends along the entire outer surface of the insulating layer 82 in the illustrated embodiment.

In the illustrated embodiment, the second length X2 is greater than the first length X1, such that the first shield 70 extends beyond the ends of the inner conductive layer 62. Likewise, the second length X2 is greater than the third length X3, such that the second shield 86 extends beyond the ends of the inner conductive layer 78. This allows the first shield 70 and the second shield 86 to better isolate the inner conductive layers 62, 78 from end effects. In some embodiments, the first shield 70 and/or the second shield 86 may include a plurality of axial sections, which may optionally be axially spaced from one another. In other embodiments, the first shield 70 and/or the second shield 86 may be continuous along the entire lengths of the tubular bodies 46, 54.

Now referring to FIG. 4, in the illustrated embodiment, the intermediate tubular body 50 defines a fourth length X4 parallel to the longitudinal axis L. The fourth length X4 is less than the second length X2. As such, the first shield 70 and the second shield 86 also isolate the intermediate tubular body 50 from external electrical fields and end effects. Furthermore, because the first shield 70 is located between the intermediate tubular body 50 and the electrode 30, the first shield 70 also shields the intermediate tubular body 50 from electrical fields produced by the electrode 30.

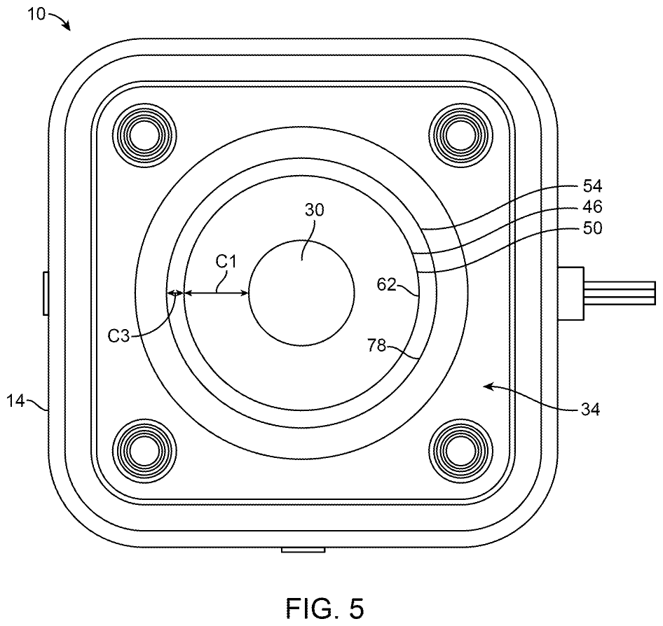

Referring to FIGS. 5-6, the inner conductive layer 62 of the inner tubular body 46 is spaced apart from the electrode 30, and the dielectric material of the body 14 fills the region between the inner conductive layer 62 and the electrode 30. As such, the inner conductive layer 62 is capacitively coupled to the electrode 30 to define a first capacitor C1, with the electrode 30 forming a first terminal, the inner conductive layer 62 forming a second terminal, and the body 14 forming the dielectric of the first capacitor C1. The first capacitor C1 is electrically coupled to a compensating circuit 100, which includes a second capacitor C2 (FIG. 6). The first capacitor C1 and the second capacitor C2 form a first capacitive divider 104, the center of which is electrically coupled to a first amplifier 108. The second capacitor C2 may have a grounded terminal and may include a different dielectric (e.g., a ceramic dielectric) than the first capacitor C1. An output of the first amplifier 108 is electrically coupled to the conductive layer 77 of the intermediate tubular body 50.

The inner conductive layer 78 of the outer tubular body 54 is spaced apart from the intermediate tubular body 50, and the dielectric material of the body 14 fills the region between the inner conductive layer 78 and the intermediate tubular body 50 (FIG. 5). As such, the inner conductive layer 78 is capacitively coupled to the conductive layer 77 of the intermediate tubular body 50 to define a third capacitor C3, with the conductive layer 77 forming a first terminal, the inner conductive layer 78 forming a second terminal, and the body 14 forming the dielectric of the third capacitor C3. The compensating circuit 100 includes a fourth capacitor C4, which forms a second capacitive divider 112 with the third capacitor C3 (FIG. 6). The fourth capacitor C4 may have a grounded terminal and may include a different dielectric (e.g., a ceramic dielectric) than the third capacitor C3. In the illustrated embodiment, the fourth capacitor C4 has the same dielectric as the second capacitor C2. The particular type of capacitors C2 and C4 (i.e., dielectric material type) are temperature-compensating or ultrastable (for example, negative-positive 0 ppm/° C. (NPO)).

With continued reference to FIG. 6, the center (output) of the second capacitive divider 112 is electrically coupled to a second amplifier 116. The outputs of the first and second amplifiers 108, 116 are electrically coupled to a first comparator 120. The output of the first amplifier 108 and the output of the first comparator 120 are electrically coupled to a second comparator 124. An output of the second comparator 124 is electrically coupled to the output 38, which may then carry the output of the second comparator 124 to a control system (not shown) of the electrical device.

The first amplifier 108 is configured to amplify a first voltage signal from the first capacitive divider 104 (and thus, the inner conductive layer 62) to an amplified first voltage signal having a first order of magnitude. The second amplifier is configured to amplify a second voltage signal from the second capacitive divider 112 (and thus, the inner conductive layer 78) to an amplified second voltage signal having a second order of magnitude, which is equal to the first order of magnitude. Because the electrode 30 is at a significantly higher voltage than the conductive layer 77 of the intermediate tubular body 50, the second amplifier 116 provides greater amplification (i.e., higher gain) than the first amplifier 108 to provide outputs from the amplifiers 108, 116 that are the same order of magnitude. The position of the intermediate tubular body 50 between the inner and outer tubular bodies 46, 54 advantageously reduces interference, which would be significantly amplified by the relatively high gain of the second amplifier 116.

A first signal from the first voltage divider 104 (signal LV1) reflects the product of the output signal of the electrode 30 and the capacitance value of the first capacitor C1 over the second capacitor C2. A second signal from the second capacitive divider 112 reflects the product of the first signal LV1 and the capacitance value of the third capacitor C3 over the fourth capacitor C4. A similar percent variation (resulting from aging/operational conditions) in dielectric permittivity may be present between capacitors C1 and C3 as they are located in similar positions within the bushing 10 and have been similar manufactured. Additionally, a similar percent variation in dielectric permittivity may be reflected between capacitors C2 and C4.

The dielectric permittivity of the capacitors C2 and C4, in particular, are at least approximately zero (as the particular type of capacitor used for C2 and C4 is ultrastable/temperature compensating and, thus, does not significantly deteriorate in electrical behavior over time or are influenced significantly at most temperatures). Therefore, a dielectric permittivity determined from the first signal LV1 represents the dielectric permittivity of the first capacitor C1. A dielectric permittivity determined from the second signal LV2 represents the dielectric permittivity of the third capacitor C3. By comparing the buffered amplitude of the first signal LV1 with the buffered amplitude of the second signal LV2, it is possible to compute the deviation of LV2 from an expected value. This derivation is referred to as an LV2 error value. Because the capacitors C1 and C3 have a similar percent variation in dielectric permittivity, the LV2 error value is representative of an LV1 error value. By adding the LV1 error value (ε(LV1)) to the first signal LV1 at the second comparator 124, the resulting output signal is a compensated measurement signal of a voltage of the electrode 30.

Thus, the present disclosure provides, among other things, a bushing including an electrical sensor configured to measure a voltage of a conductor and to communicate a signal corresponding to the measured voltage via an output. The electrical sensor includes multiple concentric capacitive sensors and shields, as well as a compensating circuit that compensates for dielectric permittivity deviation (e.g., due to temperature) and thereby increases the accuracy of the output signal. In some embodiments, the electrical sensor can maintain metering class accuracy of 0.2% to meet IEC standards 60044/61869.

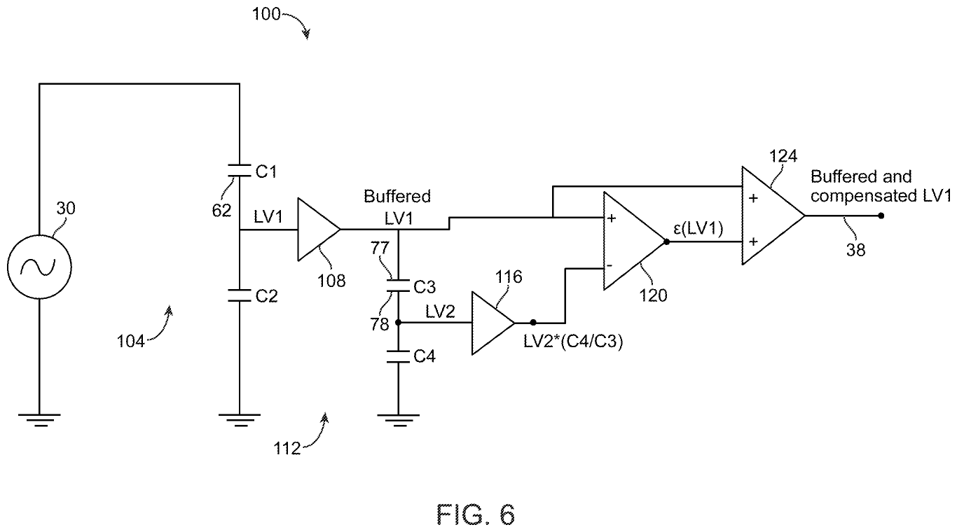

For example, with reference to FIG. 7, the electrical sensor 34 was tested for accuracy relative to a known supplied voltage at different ambient operating temperatures ranging from −5 degrees C. to 60 degrees C., plotted as line T1. Line S1 corresponds with an error percentage (or deviation between measured voltage and actual voltage) over time for the electrical sensor 34. As illustrated in FIG. 7, the error percentage associated with the electrical sensor 34 of the present disclosure varied between −0.1% and 0.2%. That is, the maximum magnitude of the error percentage was observed to be 0.2% or less in an operating temperature ranging from −5 degrees C. to 60 degrees C. For comparison, the uncompensated signal LV1 from the first voltage divider 104 was also tested, and the error percentage associated with the signal LV1 is plotted as Line U1. As illustrated in FIG. 7, the error percentage associated with the signal LV1 varied approximately proportionally with the temperature, between about −0.6% and 1.1%. Thus, the electrical sensor 34 was observed to be significantly more accurate than an uncompensated sensor under conditions of varying temperature.

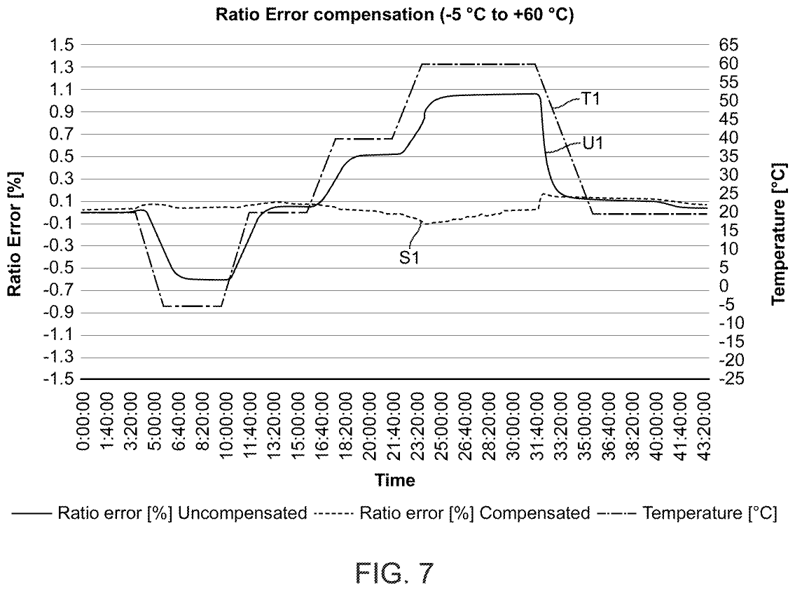

With reference to FIG. 8, the electrical sensor 34 was further tested for accuracy relative to a known supplied voltage at different ambient operating temperatures ranging from −40 degrees C. to 60 degrees C., plotted as line T2 in FIG. 8. Line S2 corresponds with an error percentage (or deviation between measured voltage and actual voltage) over time for the electrical sensor 34. As illustrated in FIG. 8, the error percentage associated with the electrical sensor 34 of the present disclosure varied between −0.3% and 0.2%. That is, the maximum magnitude of the error percentage was observed to be 0.3% or less in an operating temperature ranging from −40 degrees C. to 60 degrees C. For comparison, the uncompensated signal LV1 from the first voltage divider 104 was also tested, and the error percentage associated with the signal LV1 is plotted as Line U2. As illustrated in FIG. 8, the error percentage associated with the signal LV2 varied approximately proportionally with the temperature, between about 1.7% and −2.3%. Thus, the electrical sensor 34 was again observed to be significantly more accurate than an uncompensated sensor under conditions of varying temperature.

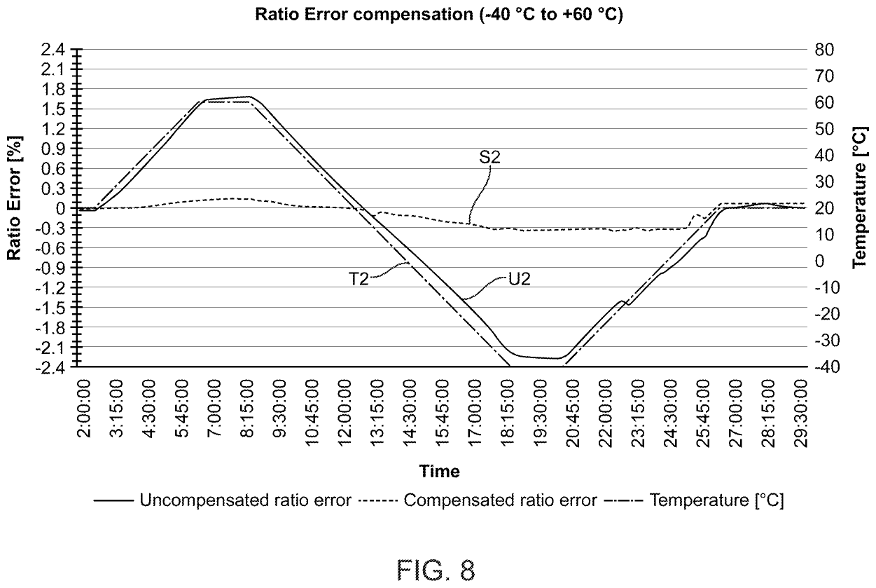

FIGS. 9-11 illustrate another embodiment of an electrical device in the form of an outdoor overhead sensor assembly 210. As described in greater detail below, the sensor assembly 210 includes an electrical sensor 234 similar to the electrical sensor 34 described above with reference to FIGS. 1-8. As such, it should be understood that aspects of the electrical sensor 34 may be incorporated into the electrical sensor 234, and vice versa.

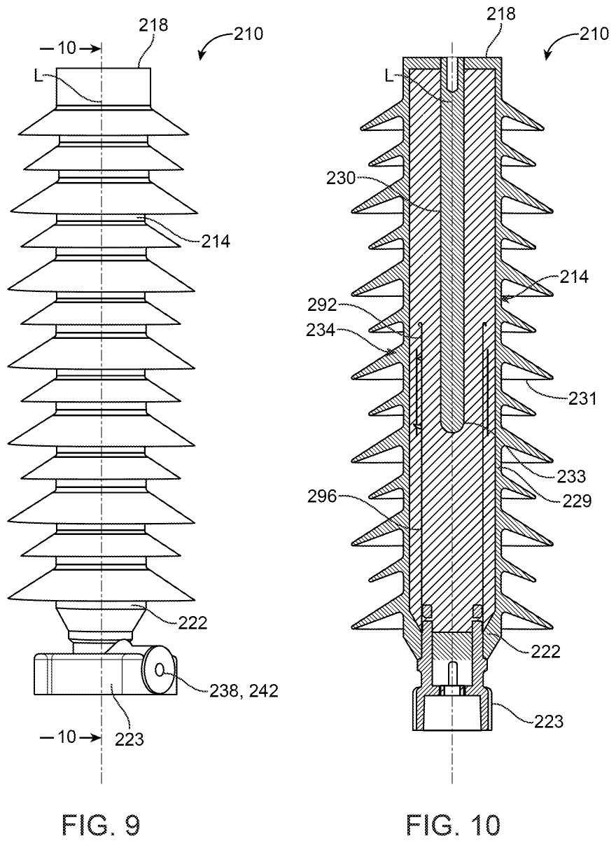

With reference to FIGS. 9-10, the illustrated assembly 210 includes a body 214 having a first end 218, a second end 222 opposite the first end 218, and a housing 223 coupled to the second end 222. The first end 218 is configured to be coupled to a voltage source, such as a power line. An electrode 230 extends along a longitudinal axis L from the first ends 218 and terminates at a distal end 233 within a central portion of the body 214. The body 214 of the illustrated assembly 210 is made of a solid dielectric material, which may be a molded dielectric material, such as an epoxy resin. In some embodiments, the epoxy resin may be a cycloaliphatic epoxy resin. The solid dielectric material has a high dielectric constant suitable for insulating the electrode 230 at the operating voltage range of the assembly 210. In the illustrated embodiment, the body 214 includes an outer sleeve 229 having a plurality of radially extending sheds 231.

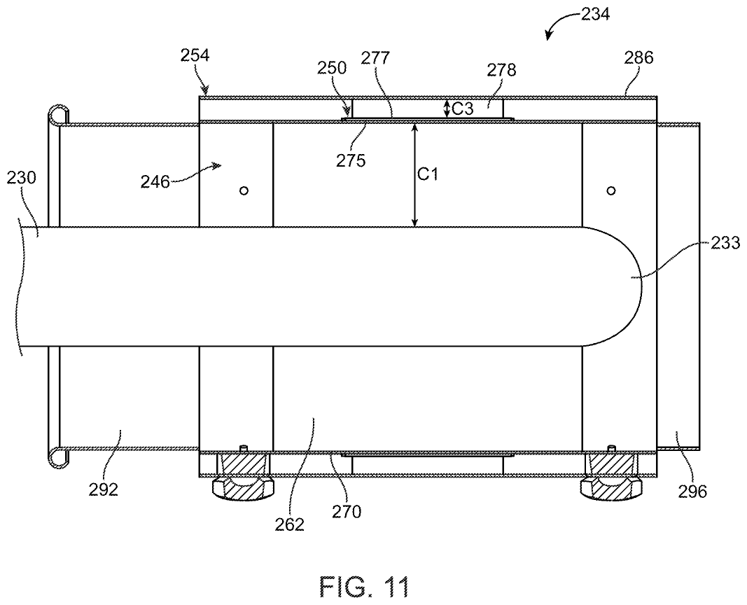

The electrical sensor 234 is configured to measure a voltage of the electrode 230 and to communicate a signal corresponding to the measured voltage via an output 238, which, in the illustrated embodiment, includes a port 242 in the housing 223 (FIG. 9). Referring to FIG. 11, the illustrated sensor 234 includes an inner tubular body 246 surrounding and spaced radially outwardly from the electrode 230, an intermediate tubular body 250 surrounding the inner tubular body 246, and an outer tubular body 254 surrounding and spaced radially outwardly from the intermediate tubular body 250. Similar to the electrical sensor 34 described above, the inner tubular body 246 includes a first inner conductive layer 262 and a first shield 270, the intermediate tubular body 250 includes an insulating layer 275 and an outer conductive layer 277, and the outer tubular body 254 includes a second inner conductive layer 278 and a second shield 286.

A third shield 292 and a fourth shield 296 extend from opposite ends of the inner tubular body 246. The third shield 292 and the fourth shield 296 are each made of a conductive material (such as a copper or brass mesh). In the illustrated embodiment, the shields 270, 286, 292, 296 are each grounded and inhibit external electrical fields from interacting with and affecting the accuracy of the electrical sensor 234.

With reference to FIGS. 10-11, the third shield 292 surrounds the electrode 230. The fourth shield 296 extends beyond the distal end 233 of the electrode 230. In the illustrated embodiment, the fourth shield 296 extends to and is coupled to the housing 223, which may also be grounded. As such, the fourth shield 296 may optionally support the electrical sensor 234 from the housing 223 during molding of the body 214. The extended length of the fourth shield 296 also provides additional shielding for the sensor 234 against end effects.

Similar to the sensor 34, the sensor 234 includes a compensating circuit and provides accurate, self-compensating voltage measurements. Thus, the present disclosure provides, among other things, an outdoor overhead voltage sensor assembly including an electrical sensor configured to measure a voltage of an electrode and to communicate a signal corresponding to the measured voltage via an output. The electrical sensor includes multiple concentric capacitive sensors and shields, as well as a compensating circuit that compensates for dielectric permittivity deviation (e.g., due to temperature) and thereby increases the accuracy of the output signal. In some embodiments, the electrical sensor can maintain metering class accuracy of 0.2% to meet IEC standards 60044/61869.

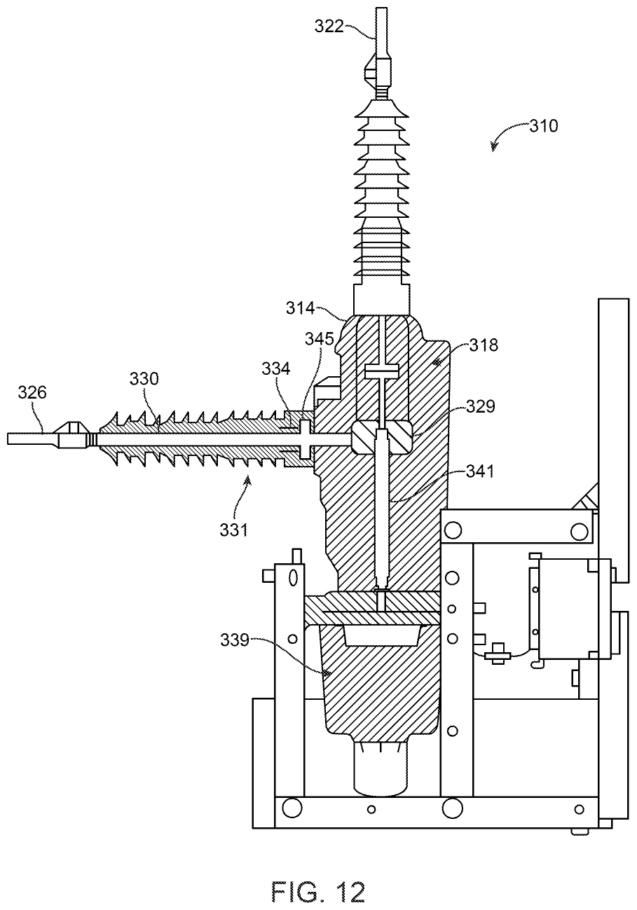

FIG. 12 illustrates an electrical device in the form of a switchgear apparatus 310. The switchgear apparatus 310 includes an electrical sensor 334 similar to the electrical sensors 34, 234 described above.

The illustrated switchgear apparatus 310 includes a housing 314, a vacuum interrupter (“VI”) assembly 318, a first terminal 322 electrically coupled to a first contact (e.g., a stationary contact) of the VI assembly 318, and a second terminal 326 electrically coupled to a second contact (e.g., a movable contact) of the VI assembly 318 via an interchange 329. In the illustrated embodiment, an electrode or conductor 330 extends from the interchange 329 to the second terminal 326 through an insulating bushing 331.

The illustrated switchgear apparatus 310 is a recloser, with an actuator assembly 339 that can operate the VI assembly 318 to selectively break and/or reestablish a conductive pathway between the first and second terminals 322, 326. The actuator assembly 339 includes an operating rod 341 extending through the housing 314 and coupled to the movable contact of the VI assembly 318. Although the switchgear apparatus 310 is illustrated individually in FIG. 12, the switchgear apparatus 310 may be part of a switchgear system including multiple switchgear 310, each associated with a different phase of a three-phase power transmission system.

In the illustrated embodiment, the electrical sensor 334 is incorporated into (e.g., molded within) the bushing 331 and is configured to measure a voltage of the conductor 330. The electrical sensor 334 may alternatively be located elsewhere within the housing 314 to measure the voltage of the conductor 330 or other components of the switchgear apparatus 310. In some embodiments, the electrical sensor 334 may be coupled to or positioned adjacent a current sensor 345, such as a Rogowski coil, for measuring a current through the conductor 330.

Similar to the sensors 34 and 234, the sensor 334 includes a compensating circuit and provides accurate, self-compensating voltage measurements, which may be used to more accurately control operation of the switchgear apparatus 310 (e.g., triggering the actuator assembly 339 in response to a detected fault). Thus, the present disclosure provides, among other things, switchgear apparatus including an electrical sensor configured to measure a voltage of a conductor and to communicate a signal corresponding to the measured voltage via an output. The electrical sensor includes multiple concentric capacitive sensors and shields, as well as a compensating circuit that compensates for dielectric permittivity deviation (e.g., due to temperature) and thereby increases the accuracy of the output signal. In some embodiments, the electrical sensor can maintain metering class accuracy of 0.2% to meet or exceed IEC standards 60044/61869.

The electrical sensors 34, 234, 334 described and illustrated herein may be incorporated into electrical devices, such as the bushing 10, sensor assembly 210, and switchgear 310, operable at a variety of voltage ratings. For example, the electrical device may be operable at voltages between 1 kV and 38 kV in some embodiments. In other embodiments, the electrical device may be operable at voltages greater than 38 kV (e.g., 72.5 kV, 140 kV, etc.).

Various features of the disclosure are set forth in the following claims.

What is claimed is:

1. An electrical sensor comprising:
an electrode;
a first capacitive divider electrically coupled between the electrode and ground, the first capacitive divider including a first output;
a second capacitive divider electrically coupled between the first output and ground, the second capacitive divider including a second output; and
a compensating circuit configured to receive, as inputs, the first output and the second output and to output a compensated voltage signal corresponding to a voltage of the electrode.

2. The electrical sensor of claim 1, wherein:
the first capacitive divider includes a first capacitor and a second capacitor,
the second capacitive divider includes a third capacitor and a fourth capacitor,
the first capacitor and the third capacitor include a first type of dielectric material,
the second capacitor and the fourth capacitor includes a second type of dielectric material, and
the second type of dielectric material is different than the first type of dielectric material.

3. The electrical sensor of claim 2, further comprising:
an inner tubular body surrounding and spaced radially outwardly from the electrode, the inner tubular body including a first inner conductive layer configured to form a first capacitive coupling with the electrode, a first shield surrounding the first inner conductive layer, and a first insulator disposed between the first inner conductive layer and the first shield;
an intermediate tubular body surrounding the inner tubular body, the intermediate tubular body including a conductive material;
an outer tubular body surrounding and spaced radially outwardly from the intermediate tubular body, the outer tubular body including a second inner conductive layer configured to form a second capacitive coupling with the conductive material of the intermediate tubular body, a second shield surrounding the second inner conductive layer, and a second insulator disposed between the second inner conductive layer and the second shield; and
a molded body encapsulating the inner tubular body, the intermediate tubular body, and the outer tubular body, the molded body made of the first type of dielectric material.

4. The electrical sensor of claim 3, wherein the electrode, the first inner conductive layer, and the molded body form the first capacitor, and wherein the conductive material of the intermediate tubular body, the second inner conductive layer, and the molded body form the third capacitor.

5. The electrical sensor of claim 1, wherein the compensated voltage signal output by the compensating circuit has an error with a magnitude of 0.2% or less over an ambient temperature range of −5 degrees C. to 60 degrees C.

6. The electrical sensor of claim 1, wherein the compensated voltage signal output by the compensating circuit has an error with a magnitude of 0.3% or less over an ambient temperature range of −40 degrees C. to 60 degrees C.

7. An electrical sensor comprising:
an electrode extending along an axis;
an inner tubular body surrounding and spaced radially outwardly from the electrode, the inner tubular body including a first inner conductive layer configured to form a first capacitive coupling with the electrode, a first shield surrounding the first inner conductive layer, and a first insulator disposed between the first inner conductive layer and the first shield;
an intermediate tubular body surrounding the inner tubular body, the intermediate tubular body including a conductive material;
an outer tubular body surrounding and spaced radially outwardly from the intermediate tubular body, the outer tubular body including a second inner conductive layer configured to form a second capacitive coupling with the conductive material of the intermediate tubular body, a second shield surrounding the second inner conductive layer, and a second insulator disposed between the second inner conductive layer and the second shield; and
a dielectric material encapsulating the inner tubular body, the intermediate tubular body, and the outer tubular body.

8. The electrical sensor of claim 7, wherein the electrode, the inner tubular body, the intermediate tubular body, and the outer tubular body are concentric.

9. The electrical sensor of claim 7, wherein the inner tubular body includes a flexible printed circuit board.

10. The electrical sensor of claim 7, wherein the outer tubular body includes a flexible printed circuit board.

11. The electrical sensor of claim 7, wherein the first inner conductive layer is electrically coupled to the conductive material of the intermediate tubular body.

12. The electrical sensor of claim 11, further comprising a first amplifier electrically coupled between the first inner conductive layer and the intermediate tubular body.

13. The electrical sensor of claim 12, further comprising a second amplifier electrically coupled to the second inner conductive layer.

14. The electrical sensor of claim 13, wherein the first amplifier is configured to amplify a first voltage signal from the first inner conductive layer to an amplified first voltage signal having a first order of magnitude, wherein the amplified first voltage signal is applied to the conductive material of the intermediate tubular body, wherein the second amplifier is configured to amplify a second voltage signal from the second inner conductive layer to an amplified second voltage signal having a second order of magnitude, and wherein the second order of magnitude is equal to the first order of magnitude.

15. The electrical sensor of claim 14, further comprising a compensating circuit configured to receive the amplified first voltage signal as a first input and the amplified second voltage signal as a second input.

16. The electrical sensor of claim 15, wherein the compensating circuit is configured to output a compensated voltage signal corresponding to a voltage of the electrode.

17. The electrical sensor of claim 7, further comprising a third shield extending from a first end of the inner tubular body.

18. The electrical sensor of claim 17, further comprising a fourth shield extending from a second end of the inner tubular body opposite the first end.

19. The electrical sensor of claim 18, wherein the first shield, and second shield, the third shield, and the fourth shield are grounded.

20. An electrical sensor comprising:
an electrode extending along an axis;
a first conductor configured to form a first capacitive coupling with the electrode;
an intermediate conductor electrically coupled to the first conductor;
a second conductor configured to form a second capacitive coupling with the intermediate conductor; and
a compensating circuit electrically coupled to the first conductor and the second conductor,
wherein the compensating circuit is configured to output a compensated voltage signal corresponding to a voltage of the electrode.

21. The electrical sensor of claim 20, wherein the first conductor, the intermediate conductor, and the second conductor are encapsulated within a dielectric material.

22. The electrical sensor of claim 20, further comprising a first amplifier electrically coupled between the first conductor and the intermediate conductor; and a second amplifier electrically coupled to the second conductor.

23. The electrical sensor of claim 22, wherein the first amplifier is configured to amplify a first voltage signal from the first conductor to an amplified first voltage signal having a first order of magnitude, wherein the second amplifier is configured to amplify a second voltage signal from the second conductor to an amplified second voltage signal having a second order of magnitude equal to the first order of magnitude, and wherein the compensating circuit is configured to receive the amplified first voltage signal as a first input and the amplified second voltage signal as a second input.

24. The electrical sensor of claim 20, further comprising a first shield surrounding the first conductor and a second shield surrounding the second conductor, wherein the intermediate conductor is disposed radially between the first shield and the second shield.
